(19) United States
(12) Patent Application Publication
(10) Pub. No.: US 2009/0260854 A1
(43) Pub. Date: Oct. 22, 2009

(54) ELECTRONIC CIRCUIT BOARD

(76) Inventors: Shingo Komura, Tokyo (JP); Katsushige Akeyama, Tokyo (JP); Motoo Yokoyama, Aichi (JP)

Correspondence Address: BIRCH STEWART KOLASCH & BIRCH, PO BOX 747, FALLS CHURCH, VA, 22040-0747, US

(21) Appl. No.: 12/440,556

(22) PCT Filed: Jul. 18, 2007
(86) PCT No.: PCT/JP2007/064193

§ 371 Date: Mar. 9, 2009

(30) Foreign Application Priority Data
Oct. 26, 2006 (JP) 2006-291447

(51) Int. Cl. H05K 1/00

(52) U.S. Cl. 174/250

(57) ABSTRACT

A resist opening 5a not covered with resist 4 around a through hole 2 provided through a board 1 is shaped so as to have a shape elongated in the direction of flow in flow soldering such that the surface tension acting on solder 6 upon the soldering is reduced.

### TECHNICAL FIELD

The present invention relates to an electronic circuit board on which an electronic circuit is arranged.

### BACKGROUND ART

In recent years, environmental matters have been seriously taken, and component mounting technologies have a tendency toward restricting use of lead. Further, European environmental controls such as WEEE (Waste Electrical and Electronic Equipment) Directive and RoHS (Restriction on Hazardous Substances) do not approve the use of lead in electrical and electronic equipment. Thus, the manufacture of products of electrical and electronic apparatuses is forced to greatly change.

Under the circumstances, flow soldering using lead-free solder is carried out in the manufacture of electronic circuit boards. However, the lead-free solder has poorer wettability than lead solder and thus does not completely conform to a through hole, especially a small-diameter through hole (mini via hole) (e.g., about 0.3 mm in diameter) in flow soldering process, resulting in forming a large solder ball at the opening of the through hole.

FIG. 5 shows an enlarged cross-section of the portion of a through hole when a wave soldering which the through hole is provided is flow-soldered with a lead-free solder. A board 101 is provided with a through hole 102. The board 101 is copper-plated (copper foil) on the front surface and the inner wall surface of the through hole 102 thereof, and a surface pattern 103 of the board 101 and an electric path (not shown) on the backside of the board 101 are connected to each other through a plated layer 102a provided over the inner wall surface of the through hole 102. Further, a resist 104 is applied to the surface of the pattern 103 in order for solder not to adhere to the surface of the pattern in a flow soldering process using lead-free solder. In this case, if the resist 104 can completely plug the through hole 102, there is no problem; however, when the board 101 has a thickness of 0.8 mm or more, e.g., the resist cannot fully plug the through hole 102. This produces minute holes within the resist covering the through hole 102, and in the next process, acidic copper foil cleaning solution enters the through hole therethrough. However, the hole is extremely minute, and thus the copper foil cleaning solution entrapped therein cannot be completely removed, which may cause the copper foil to be corroded. For this reason, the peripheral portion of the through hole 102 is provided with a resist opening 104a that is not coated with resist.

When such a board 1 is flow-soldered with lead-free solder, a land 103a that is part of the pattern 103 exposed within the resist opening 104a has solder adhered thereto as shown in FIG. 5, resulting in the adhered solder forming a solder ball 105. The solder ball 105 becomes spherical by its surface tension. The solder ball 105 only adheres to part of the extremely narrow land 103a (width of approximately 0.1 mm). Thus, the solder ball has a small adhesive force to the land 103a and can fall off therefrom by the expansion and/or vibration of the board 101. In the event that the solder ball 105 falls off therefrom, failures such as short circuit between the terminals of an IC and the like can occur.

In order for such a solder ball 105 not to be formed at the opening of the through hole 102, it is contemplated to fill the through hole 102 with resist liquid for printing with solder resist and ink for silk printing as disclosed in Patent Document 1.

Patent Document 1: JP-A-1994-125164

However, when the through hole is filled with the resist liquid and the ink as described in Patent Document 1, gas or liquid is confined within the minute holes formed within the through hole. Thus, there are problems such that the gas generated from the liquid may expand to be burst due to the rise of the ambient temperature of the board, or the liquid itself may corrode the plated copper layer over the through hole.

The present invention has been made to solve the above-mentioned problems, and an object of the present invention is to provide an electronic circuit board where the short circuit caused by falling off of the solder ball and the failures caused by filling the through hole therewith do not occur.

### DISCLOSURE OF THE INVENTION

The electronic circuit board according to the present invention is characterized in that a resist opening that is not covered with resist around a through hole provided at the board is shaped such that the surface tension acting on solder upon soldering is reduced.

According to the present invention, the resist opening around the through hole is shaped such that the surface tension acting on solder upon the soldering is lowered. Thus, even when the circuit board is flow-soldered with lead-free solder, the solder solidified around the through hole has a flat shape, not forming a solder ball. Moreover, the solder adheres firmly to a land formed by the resist opening and does not fall off therefrom by expansion and contraction, and/or vibration of the board.

### BRIEF DESCRIPTION OF THE DRAWINGS

FIG. 1 is a partial sectional view of an electronic circuit board in accordance with the first embodiment of the present invention.

FIG. 2 is an underneath plan view of the electronic circuit board in accordance with the first embodiment.

FIG. 3 is an underneath plan view of an electronic circuit board in accordance with the second embodiment of the present invention.

FIG. 4 is a schematic view showing examples of the resist opening thereof.

FIG. 5 is a sectional view of a solder ball formed surrounding a through hole.

### BEST MODE FOR CARRYING OUT THE INVENTION

Embodiments of the present invention will now be described with reference to the accompanying drawings in order to explain the present invention in more detail.

### First Embodiment

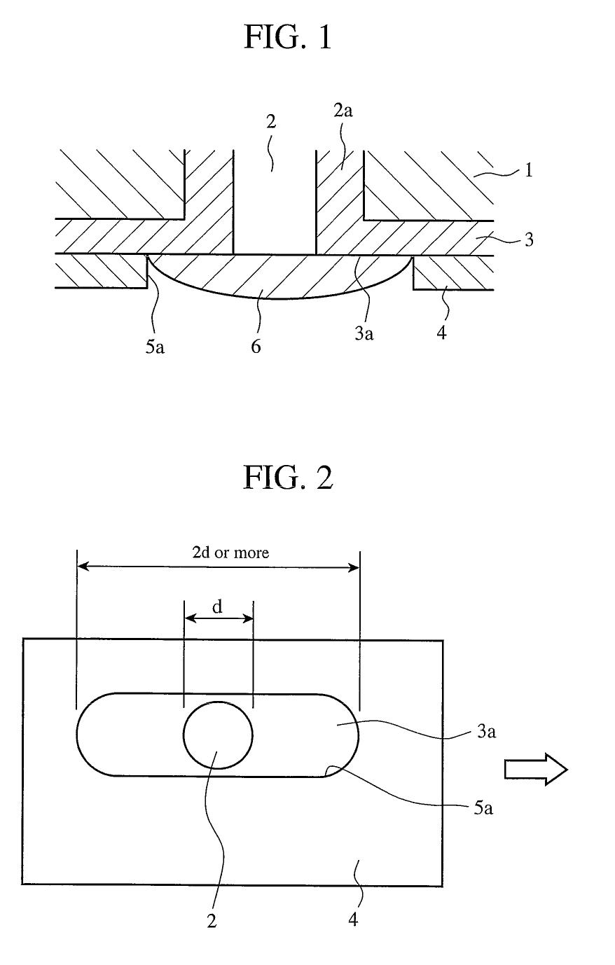

The first embodiment of the present invention will next be discussed by reference to the drawings in detail. FIG. 1 shows a partial cross-section of an electronic circuit board in accordance with the first embodiment and FIG. 2 shows an underneath plan view of the board that is not yet soldered.

In the electronic circuit board, aboard 1 having a large number of electronic components mounted thereon is provided with a through hole 2 for connecting the front and back of the board 1, extending through the board 1 perpendicularly with respect to the board. The board 1 is copper-plated on the surface thereof and the inner wall surface of the through hole 2 and is provided with a copper foil pattern 3. In the figure, reference numeral 2a denotes a plated layer on the inner wall surface of the through hole 2. Resist 4 is applied over the surface of the board 1; however, a resist opening 5a having a predetermined shape is formed around the through hole 2, thus providing thereon a land 3a formed by partially exposing the copper foil pattern 3.

The resist opening 5a is shaped such that the surface tension acting on lead-free solder adhering to the resist opening 5a is lowered. The shape of the resist opening by which the surface tension acting on the solder is lowered is provided with a shape other than a circular shape. More specifically, the resist opening is formed in an oval shape surrounding the through hole 2 as shown in FIG. 2. The oval resist opening 5a is oriented with its longitudinal direction parallel to the direction of flow when the board is flow-soldered. In this way, the longitudinal direction of the resist opening 5a corresponds to the direction of flow (the direction in which the board 1 is moved in flow-soldering indicated by the arrow of the figure) in soldering, which causes the solder to easily mount to the land 3a and forms a solder 6 thereon as shown in FIG. 1. The solder 6 adheres to the large land 3a to be flat-shaped, not ball-shaped.

It is preferable that the resist opening 5a has a sufficient length in the longitudinal direction; however, it is preferable from the viewpoint of high-density mounting of components that the resist opening 5a, i.e., the land 3a is as small as possible. Thus, the land is arranged to have a maximum length in relation to the mounting density of components. A solder ball is apt to be formed when the exposed copper foil portion has a diameter of 0.6 mm or less in the case where the through hole 2 has a diameter of 0.3 mm or less. Therefore, the length in the longitudinal direction of the resist opening 5a should be 2 d or more, which is twice the diameter d of the through hole 2.

As mentioned above, according to the electronic circuit board of the first embodiment, the solder 6 at the opening of the through hole 2 adheres to the land 3a longitudinally elongated and having a large area. Thus, the surface tension acting on the solder is weakened, and thereby the solder 6 becomes flat and further adheres strongly to the land 3a. Therefore, the solder 6 does not fall off therefrom even if the board 1 is expanded and vibrated. Further, this prevents the solder 6 from projecting from the board 1 and thereby prevents the solder 6 from falling off because of its hitting against other portions. For this reason, there are no occurrences of failures such as the short circuit of ICs that are caused by falling-off of the solder. Furthermore, the electronic circuit board according to the present invention does not have a structure where the through hole 2 is filled therewith, and thus inconveniences caused by filling the through hole do not arise.

### Second Embodiment

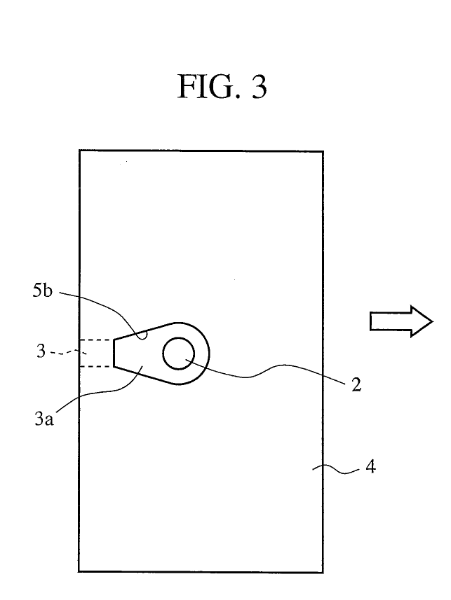

FIG. 3 shows a plan view of an electronic circuit board according to the second embodiment of the present invention.

The electronic circuit board is an example in which the present invention is applied to a through hole 2 used for connecting a signal line, and so on. The copper foil area around the through hole used for the signal line is basically small, and a connecting portion where the through hole and the signal line and so on are connected to each other is commonly teardrop-shaped. Therefore, a resist opening 5b formed around the through hole 2 used for the signal line and so on should be also given the shape of a teardrop. It should be understood that in the example, the resist opening 5b has a longitudinal length (2 d) twice the diameter (d) of the through hole 2.

The resist opening 5b is thus formed in the shape of a teardrop, thus increasing an adhering space where a solder 6 adhering to the resist opening 5b adheres to a land 3a that is an exposed copper foil and increasing the adhesive force of the solder thereto. Therefore, the solder adhering around the through-hole cannot fall off even if the board 1 is expanded or vibrated.

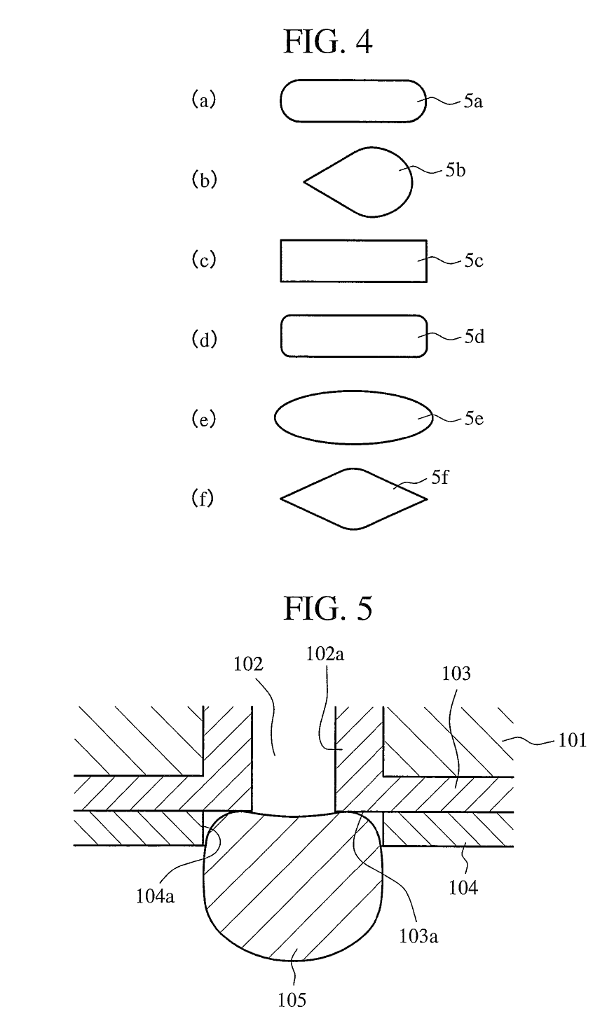

The shape of the resist opening is not limited to the oval shape (FIG. 4(a)) and teardrop shape (FIG. 4(b)) discussed in the first and second embodiments, respectively; however, it is contemplated for the resist opening to have a variety of shapes; a rectangular shape 5c, rounded-corner rectangular shape 5d, elliptical shape 5e, bobbin-shape 5f, and so on, as shown in FIG. 4(c)-FIG. 4(f).

### INDUSTRIAL APPLICABILITY

As described above, the electronic circuit board according to the present invention is arranged such that possible inconveniences due to falling off of the solder ball and filling of the through hole are eliminated by means of shaping the resist opening surrounding the through hole so that the surface tension acting on the solder becomes small, and thus the electronic circuit board is suitable for use in electronic circuit boards on which an electronic circuit is arranged.

1. An electronic circuit board wherein a resist opening that is not covered with resist around a through hole provided through the board is shaped such that the surface tension acting on solder during the soldering is lowered.

2. The electronic circuit board according to claim 1, wherein the resist opening is formed in a shape different from a circular shape.

3. The electronic circuit board according to claim 1, wherein the resist opening is formed in a shape selected from the group consisting of an oval, teardrop-shape, rectangular, rounded-corner rectangular, elliptical and bobbin-shape.

4. The electronic circuit board according to claim 1 wherein the longitudinal length of the resist opening is 2 d or more, where the diameter of the through hole is d.

5. The electronic circuit board according to claim 1, wherein the longitudinal direction of the resist opening corresponds to the direction of flow in flow soldering.
